(19) United States
(12) Patent Application Publication
(10) Pub. No.: US 2026/0075877 A1
(43) Pub. Date: Mar. 12, 2026

(54) INTEGRATED PROCESS AND PROCESSING SYSTEM FOR MANUFACTURING PMOS TRANSISTORS

(71) Applicant: Applied Materials, Inc., Santa Clara, CA (US)

(72) Inventors: Srinivas Gandikota, Santa Clara, CA (US); Hsin-Jung Yu, Santa Clara, CA (US); Tengzhou Ma, San Jose, CA (US); Geetika Bajaj, Cupertino, CA (US); Lin Sun, Milpitas, CA (US); Yixiong Yang, Fremont, CA (US)

(73) Assignee: Applied Materials, Inc., Santa Clara, CA (US)

(21) Appl. No.: 18/827,184

(22) Filed: Sep. 6, 2024

(51) Int. Cl. H01L 29/423; H01L 21/477; H01L 21/67; H01L 21/8234; H01L 27/088; H01L 29/06; H01L 29/08; H01L 29/66; H01L 29/775; H01L 29/786

(52) U.S. Cl. CPC H10D 30/6735; H10D 30/014; H10D 30/43; H10D 30/6757; H10D 62/121; H10D 62/151; H10D 84/0128; H10D 84/038; H10D 84/83; H10P 72/0454; H10P 95/90

(57) ABSTRACT

Methods of manufacturing electronic devices and integrated processing systems for manufacturing electronic devices (e.g., P-channel metal-oxide-semiconductor (PMOS) transistors) are described. The methods include depositing an interfacial layer on a top surface of a channel located between a source region and a drain region on a substrate; depositing a high-κ dielectric layer on the interfacial layer; depositing a dipole depinning layer on the high-κ dielectric layer; depositing a P-metal layer on the dipole depinning layer; and depositing a capping layer on the P-metal layer. The method is performed in situ in an integrated processing system.

### TECHNICAL FIELD

Embodiments of the present disclosure pertain to the field of electronic device manufacturing, and in particular, to transistors. More particularly, embodiments of the present disclosure are directed to integrated processes and processing systems for manufacturing P-channel metal-oxide-semiconductor (PMOS) transistors.

### BACKGROUND

Integrated circuits have evolved into complex devices that can include millions of transistors, capacitors, and resistors on a single chip. In the course of integrated circuit evolution, functional density (i.e., the number of interconnected devices per chip area) has generally increased while geometry size (i.e., the smallest component (or line) that can be created using a fabrication process) has decreased.

The transistor is a key component of most integrated circuits. Many transistors may be formed on an electronic device in addition to capacitors, inductors, resistors, diodes, conductive lines, or other elements, depending on the circuit design. Control of the dimensions of the integrated circuit device structure is a key challenge for present and future technology generations.

Examples of transistor structures include a planar structure, a fin field effect transistor (FinFET) structure, and a horizontal gate-all-around (hGAA) structure. The horizontal gate-all-around (hGAA) structure includes several lattice matched channels suspended in a stacked configuration and connected by source/drain regions. It has been found that the horizontal gate-all-around (hGAA) structure provides good electrostatic control and can find broad adoption in complementary-metal-oxide-semiconductor (CMOS) wafer manufacturing.

Generally, a metal-oxide-semiconductor (MOS) is a structure obtained by growing a high-κ dielectric layer on a layer of silicon oxide (SiOx) on top of a silicon substrate, followed by depositing a layer of metal or polycrystalline silicon on the high-κ dielectric layer. A CMOS device is a MOS device consisting of paired p-channel and n-channel transistors. An “NMOS” or “NFET” is a MOS transistor where the active carriers are electrons flowing between n-type source and drain regions in an electrostatically formed n-channel in a p-type silicon substrate. The abbreviations “NMOS” and “NFET” can be used interchangeably herein. A “PMOS” or “PFET” is a P-channel MOS transistor where the active carriers are holes flowing between p-type source and drain regions in an electrostatically formed p-channel in an n-type silicon substrate. The abbreviations “PMOS”and “PFET”can be used interchangeably herein.

With more advanced device scaling, it is becoming more challenging for PMOS high-κ metal gate (HKMG) stacks to achieve the desired bandedge performance because of the significant flatband voltage (V_{fb}) rolloff, potentially due to Fermi level pinning.

Accordingly, there is a need for methods of manufacturing electronic devices, e.g., PMOS HKMG stacks, that achieve desired bandedge performance.

### SUMMARY

One or more embodiments of the disclosure are directed to a method of manufacturing an electronic device. In one or more embodiments, the method comprises depositing an interfacial layer on a top surface of a channel located between a source and a drain on a substrate; depositing a high-κ dielectric layer on the interfacial layer; depositing a dipole depinning layer on the high-κ dielectric layer; depositing a P-metal layer on the dipole depinning layer; and depositing a capping layer on the P-metal layer. The method is performed in situ in an integrated processing system.

Additional embodiments of the disclosure are directed to a method of manufacturing an electronic device. In one or more embodiments, the method comprises depositing an interfacial layer comprising silicon oxide (SiOx) on a top surface of a silicon (Si) channel located between a source and a drain on a substrate; depositing a high-κ dielectric layer comprising hafnium oxide (HfOx) on the interfacial layer; depositing a dipole depinning layer on the high-κ dielectric layer; performing a low temperature oxygen (O₂) and/or nitrogen (N₂) annealing process; performing a rapid thermal process (RTP), the RTP including one or more of a spike anneal process, a nanosecond anneal process, or a millisecond anneal process; depositing a P-metal layer on the dipole depinning layer; depositing a capping layer on the P-metal layer; performing the low temperature oxygen (O₂) and/or nitrogen (N₂) annealing process; and selectively removing the capping layer. The method is performed in situ in an integrated processing system.

Further embodiments of the disclosure are directed to a processing system. In one or more embodiments, the processing system comprises a central transfer station comprising a robot configured to move one or more substrates; a plurality of process stations, each process station connected to the central transfer station and providing a processing region separated from processing regions of adjacent process stations; and a controller connected to the central transfer station and the plurality of process stations. The controller is configured to activate the robot to move the one or more substrates between process stations. The robot is configured to perform a method comprising: depositing an interfacial layer on a top surface of a channel located between a source and a drain on the substrate; depositing a high-κ dielectric layer on the interfacial layer; depositing a dipole depinning layer on the high-κ dielectric layer; depositing a P-metal layer on the dipole depinning layer; and depositing a capping layer on the P-metal layer. The method is performed in situ.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limitation in the figures of the accompanying drawings in which like references indicate similar elements.

FIG. 1 illustrates a process flow diagram of a method of manufacturing an electronic device according to one or more embodiments of the present disclosure;

FIG. 2 illustrates a cross-sectional view of a substrate according to one or more embodiments of the present disclosure; and

FIG. 3 illustrates a schematic representation of a processing system according to one or more embodiments of the present disclosure.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “about” as used herein means approximately or nearly and in the context of a numerical value or range set forth means a variation of ±15% or less, of the numerical value. For example, a value differing by ±14%, ±10%, ±5%, ±2%, ±1%, ±0.5%, or ±0.1% would satisfy the definition of “about.”

Spatially relative terms, such as “beneath,” “below,” “lower,” “above,” “upper” and the like, may be used herein for ease of description to describe one element or feature's relationship to another element(s) or feature(s) as illustrated in the Figures. It will be understood that the spatially relative terms are intended to encompass different orientations of a device in use or operation in addition to the orientation depicted in the Figures. For example, if the device in the Figures is turned over, elements described as “below” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “some embodiments,” “certain embodiments,” “one or more embodiments,” or “an embodiment” means that a particular feature, structure, material, or characteristic described in connection with the embodiment is included in at least one embodiment of the disclosure. Thus, the appearances of the phrases such as “in one embodiment,” “in some embodiments,” “in certain embodiments,” “in one or more embodiments,” or “in an embodiment” in various places throughout this specification are not necessarily referring to the same embodiment of the disclosure. Furthermore, the particular features, structures, materials, or characteristics may be combined in any suitable manner in one or more embodiments.

As used in this specification and the appended claims, the term “substrate” refers to a surface, or portion of a surface, upon which a process acts. It will also be understood by those skilled in the art that reference to a substrate can refer to only a portion of the substrate unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon (including doped silicon or undoped silicon), silicon oxide, strained silicon, silicon on insulator (SOI), carbon doped silicon oxides, amorphous silicon, germanium, gallium arsenide, and any other materials such as metals, metal nitrides, metal alloys, and other conductive materials, depending on the application. Substrates include, without limitation, semiconductor substrates.

Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an under-layer formed on the substrate as disclosed in more detail below, and the term “substrate surface” is intended to include such under-layer as the context indicates. Thus, for example, where a film/layer or partial film/layer has been deposited onto a substrate surface, the exposed surface of the newly deposited film/layer becomes the substrate surface.

The substrate may have one or more features formed therein, one or more layers formed thereon, or combinations thereof. The shape of the feature can be any suitable shape including, but not limited to, trenches, holes and vias (circular or polygonal). As used in this regard, the term “feature” refers to any intentional surface irregularity. Suitable examples of features include but are not limited to trenches, which have a top, two sidewalls comprising, for example, a dielectric material, and a bottom extending into the substrate, the bottom comprising, for example, a metallic material, or vias which have one or more sidewall extending into the substrate to a bottom, and slot vias.

The features described herein can extend vertically into the substrate and/or laterally within the substrate. Unless specifically indicated otherwise, the features described herein are not limited to either of a vertically extending feature or a laterally extending feature. In one or more embodiments, the substrate comprises at least one vertically extending feature. In one or more embodiments, the substrate comprises at least one laterally extending feature. In one or more embodiments, the substrate comprises at least one vertically extending feature and at least one laterally extending feature.

The features described herein can have any suitable aspect ratio (ratio of the depth of the feature to the width of the feature). In one or more embodiments, the aspect ratio of the features described herein is greater than or equal to about 1:1, 2:1, 5:1, 10:1, 15:1, 20:1, 25:1, 30:1, 35:1, 40:1, 50:1, 60:1, 70:1, 80:1, 90:1, 100:1, 125:1, or 150:1. In one or more embodiments, the aspect ratio of the features described herein is in a range of from 1:1 to 150:1.

The term “on” indicates that there is direct contact between elements. The term “directly on” indicates that there is direct contact between elements with no intervening elements.

As used herein, the term “in situ” refers to processes that are all performed in the same processing chamber or within different processing chambers that are connected as part of an integrated processing system, such that each of the processes are performed without an intervening vacuum break. As used herein, the term “ex situ” refers to processes that are performed in at least two different processing chambers such that one or more of the processes are performed with an intervening vacuum break. In some embodiments, processes are performed without breaking vacuum or without exposure to ambient air.

As used in this specification and the appended claims, the terms “precursor”, “reactant”, “reactive gas” and the like are used interchangeably to refer to any gaseous species or vapor species that can react with the substrate surface.

One or more of the layers deposited on the substrate or substrate surface are continuous. As used herein, the term “continuous” refers to a layer that covers an entire exposed surface without gaps or bare spots that reveal material underlying the deposited layer. A continuous layer may have gaps or bare spots with a surface area less than about 15% or less than about 10% of the total surface area of the layer.

As used in this specification and the appended claims, the terms “precursor”, “reactant”, “reactive gas” and the like are used interchangeably to refer to any gaseous species that can react with the substrate surface.

As used herein, “chemical vapor deposition (CVD)” refers to a process in which a substrate surface is exposed to precursors and/or reactants simultaneously or substantially simultaneously. As used herein, “substantially simultaneously” refers to either co-flow or where there is overlap for a majority of exposures of the precursors and/or reactants. As used herein, “pulsed CVD” refers to a process in which one of the precursor or the reactant is pulsed intermittently, and the other of the precursor of the reactant is flowed continuously. Plasma-enhanced chemical vapor deposition (PECVD) methods add a plasma exposure to traditional CVD methods. In some PECVD methods, an inert gas is provided as the plasma. Embodiments described herein in reference to a PECVD process can be carried out using any suitable deposition system.

“Atomic layer deposition” or “cyclical deposition” as used herein refers to the sequential exposure of two or more reactive species to deposit a layer of material on a substrate surface. The substrate, or portion of the substrate, is exposed separately to the two or more reactive species which are introduced into a reaction zone of a processing chamber. In a time-domain ALD process, exposure to each reactive species is separated by a time delay to allow each compound to adhere and/or react on the substrate surface and then be purged from the processing chamber. These reactive species are said to be exposed to the substrate sequentially.

As used herein, the terms “purge” or “purging” each independently include any suitable purge process that removes unreacted precursor/reactant, reaction products, and by-products from the process region (e.g., a processing chamber). The suitable purge process includes moving the substrate through a gas curtain to a portion or sector of the processing region that contains none or substantially none of the precursor/reactant. In one or more embodiments, purging the processing chamber comprises applying a vacuum. In some embodiments, purging the processing region comprises flowing a purge gas over the substrate. In some embodiments, the purge process comprises flowing an inert gas. In one or more embodiments, the purge gas is selected from one or more of nitrogen (N₂), helium (He), and argon (Ar). In some embodiments, the first reactive species is purged from the processing chamber for a time duration in a range of from 0.1 seconds to 30 seconds, from 0.1 seconds to 10 seconds, from 0.1 seconds to 5 seconds, from 0.5 seconds to 30 seconds, from 0.5 seconds to 10 seconds, from 0.5 seconds to 5 seconds, from 1 seconds to 30 seconds, from 1 seconds to 10 seconds, from 1 seconds to 5 seconds, from 5 seconds to 30 seconds, from 5 seconds to 10 seconds or from 10 seconds to 30 seconds before exposing the substrate to the second reactive species.

In a spatial ALD process, different portions of the substrate surface, or material on the substrate surface, are exposed simultaneously to the two or more reactive species so that any given point on the substrate is substantially not exposed to more than one reactive species simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time delay. Next, a second precursor or compound B is pulsed into the reaction zone followed by a second delay. During each time delay, a purge gas is introduced into the processing chamber to purge the reaction zone or otherwise remove any residual reactive species or reaction by-products from the reaction zone. Alternatively, the purge gas may flow continuously throughout the deposition process so that only the purge gas flows during the time delay between pulses of reactive species. The reactive species are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the predetermined thickness.

In an embodiment of a spatial ALD process, a first reactive gas and second reactive gas are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas.

Plasma-enhanced atomic layer deposition (PEALD) methods add a plasma exposure to traditional ALD methods. In some PEALD methods, an inert gas is provided as the plasma. Embodiments described herein in reference to a PEALD process can be carried out using any suitable deposition system.

As used herein, the terms “thermal” or “thermal process(es)” each independently refer to a deposition technique that does not involve the use of plasma. As used herein, the term “plasma” refers to a composition have ionically charged species and uncharged neutral and radical species.

As used herein, as will be understood by the skilled artisan, a layer/film which is “conformal” or “conformally deposited” refers to a layer/film where the thickness is about the same throughout. A layer/film which is conformal varies in thickness by less than or equal to about 5%, 2%, 1% or 0.5%.

Transistors are circuit components or elements that are often formed on semiconductor devices. Depending upon the circuit design, in addition to capacitors, inductors, resistors, diodes, conductive lines, or other elements, transistors are formed on a semiconductor device. Generally, a transistor includes a gate formed between source and drain regions. In one or more embodiments, the source and drain regions include a doped region of a substrate, such as a semiconductor substrate, and exhibit a doping profile suitable for a particular application. The gate is positioned over the channel region and includes a gate dielectric interposed between a gate electrode and the channel region in the semiconductor substrate.

As used herein, the term “field effect transistor” or “FET” refers to a transistor that uses an electric field to control the electrical behavior of the device. Field effect transistors are voltage controlled devices where their current carrying ability is changed by applying an electric field. Field effect transistors generally display very high input impedance at low temperatures. The conductivity between the drain and source terminals is controlled by an electric field in the device, which is generated by a voltage difference between the body and the gate of the device. The FET's three terminals are source (S), through which the carriers enter the channel; drain (D), through which the carriers leave the channel; and gate (G), the terminal that modulates the channel conductivity. Conventionally, current entering the channel at the source (S) is designated I_{S} and current entering the channel at the drain (D) is designated I_{D}. Drain-to-source voltage is designated V_{DS}. By applying voltage to gate (G), the current entering the channel at the drain (i.e. I_{D}) can be controlled.

The metal-oxide-semiconductor field-effect transistor (MOSFET) is a type of field-effect transistor (FET) and is used in integrated circuits and high speed switching applications. MOSFET has an insulated gate, whose voltage determines the conductivity of the device. This ability to change conductivity with the amount of applied voltage is used for amplifying or switching electronic signals. A MOSFET is based on the modulation of charge concentration by a metal-oxide-semiconductor (MOS) capacitance between a body electrode and a gate electrode located above the body and insulated from all other device regions by a gate dielectric layer. Compared to the MOS capacitor, the MOSFET includes two additional terminals (source and drain), each connected to individual highly doped regions that are separated by the body region. These regions can be either p or n type, but they are both of the same type, and of opposite type to the body region. The source and drain (unlike the body) are highly doped as signified by a “+” sign after the type of doping.

Generally, a metal-oxide-semiconductor (MOS) is a structure obtained by growing a high-κ dielectric layer on a layer of silicon oxide (SiOx) on top of a silicon substrate, followed by depositing a layer of metal or polycrystalline silicon on the high-κ dielectric layer. A CMOS device is a MOS device consisting of paired p-channel and n-channel transistors.

If the MOSFET is an n-channel or NMOS FET (‘NMOS” or “NFET”), then the source and drain are n+ regions and the body is a p region. If the MOSFET is a p-channel or PMOS FET (“PMOS” or “PFET”), then the source and drain are p+ regions and the body is an n region. The source is so named because it is the source of the charge carriers (electrons for n-channel, holes for p-channel) that flow through the channel; similarly, the drain is where the charge carriers leave the channel.

An “NMOS” or “NFET” is a MOS transistor where the active carriers are electrons flowing between n-type source and drain regions in an electrostatically formed n-channel in a p-type silicon substrate. A “PMOS” or “PFET” is a P-channel MOS transistor where the active carriers are holes flowing between p-type source and drain regions in an electrostatically formed p-channel in an n-type silicon substrate.

In one or more embodiments, the “PMOS” or “PFET” comprises a silicon germanium (SiGe) channel between a source region and a drain region and the “NMOS” or “NFET” comprises a silicon (Si) channel between a source region and a drain region. In one or more embodiments, the “PMOS” or “PFET” comprises a silicon (Si) channel between the source region and the drain region.

Shrinking of the materials currently used as NMOS and PMOS have become a challenge due to changes in basic properties, such as threshold voltage (Vₜ). The Vₜ tuning range will be limited by the film thickness variation with further scaling down of device sizes.

As used herein, the term “fin field-effect transistor (FinFET)” refers to a MOSFET transistor built on a substrate where the gate is placed on two, three, or four sides of the channel or wrapped around the channel, forming a double gate structure. FinFET devices have been given the generic name FinFETs because the source/drain region forms “fins” on the substrate. FinFET devices have fast switching times and high current density.

As used herein, the term “gate-all-around (GAA),” is used to refer to an electronic device, e.g., a transistor, in which the gate material surrounds the channel region on all sides. The channel region of a GAA transistor may include nanowires, nanosheets, nanoslabs, bar-shaped channels, or other suitable channel configurations known to one of skill in the art. In one or more embodiments, the channel region of a GAA device has multiple horizontal nanowires or horizontal bars vertically spaced, making the GAA transistor a stacked horizontal gate-all-around (hGAA) transistor.

As used herein, the term “nanowire” refers to a nanostructure, with a diameter on the order of a nanometer (10⁻⁹ meters). Nanowires can also be defined as the ratio of the length to width being greater than 1000. Alternatively, nanowires can be defined as structures having a thickness or diameter constrained to tens of nanometers or less and an unconstrained length. Nanowires are used in transistors and some laser applications, and, in one or more embodiments, are made of semiconducting materials, metallic materials, insulating materials, superconducting materials, or molecular materials. In one or more embodiments, nanowires are used in transistors for logic CPU, GPU, MPU, and volatile (e.g., DRAM) and non-volatile (e.g., NAND) devices. As used herein, the term “nanosheet” refers to a two-dimensional nanostructure with a thickness in a scale ranging from about 0.1 nm to about 1000 nm, or from 0.5 nm to 500 nm, or from 0.5 nm to 100 nm, or from 1 nm to 500 nm, or from 1 nm to 100 nm, or from 1 nm to 50 nm.

Embodiments of the present disclosure pertain to the field of electronic device manufacturing, and in particular, to transistors. One or more embodiments are directed methods of manufacturing logic devices. One or more embodiments are directed methods of manufacturing “PMOS” or “PFET” structures and/or “NMOS” or “NFET” structures.

Some embodiments advantageously provide an integrated solution to achieve desired bandedge workfunction for PMOS transistors by using a clustered-tool configuration without an intervening vacuum break. Advantageously, in using the clustered-tool configuration without an intervening vacuum break described herein, oxidation between steps of the integration flow will be minimal, such that capacitive effective thickness (CET) penalty will advantageously be minimized. For example, when interfacial layer thickness (e.g., silicon oxide thickness) increases by one Angstrom, CET penalty increases by one Angstrom. The CET penalty occurs due to additional oxygen being picked up by the metal atoms due to ambient exposure. The integrated process and clustered-tool configuration without an intervening vacuum break described herein advantageously minimize CET penalty.

Embodiments of the present disclosure advantageously provide electronic devices which, instead of having a p-metal directly on a high-κ dielectric layer, include a dipole depinning layer deposited to advantageously minimize flatband voltage (V_{fb}) rolloff. Some embodiments advantageously provide methods of manufacturing electronic devices that provide improved bandedge performance, e.g., improved flatband voltage (V_{fb}).

In one or more embodiments, the addition of the dipole depinning layer may advantageously increase the flatband voltage (V_{fb}) by more than 100 mV when compared to a PMOS stack that does not have a depinning layer.

Advantageously, the dipole depinning layer acts as a dipole forming layer upon rapid thermal processing (RTP) and can form dipoles, thereby boosting threshold voltage (Vₜ) of the transistor.

Advantageously, in one or more embodiments, the dipole depinning layer has depinning properties, e.g., the dipole depinning layer increases the flatband voltage (V_{fb}) by more than 100 mV when compared to a PMOS stack that does not have a depinning layer, thereby mitigating Fermi level pinning effect, and the dipole depinning layer acts as a dipole forming layer upon rapid thermal processing (RTP) and can form dipoles, thereby boosting threshold voltage (Vₜ) of the transistor.

In one or more embodiments, the deposition technique used to deposit the dipole depinning layer combines deposition of a P-dipole material and P-metal material and advantageously obviates a dipole removal step, thereby simplifying the existing integration flow and reducing the integration costs.

The embodiments of the disclosure are described by way of the Figures, which illustrate electronic devices (e.g., transistors) and methods of manufacturing transistors in accordance with one or more embodiments of the disclosure. The skilled artisan will recognize that the disclosed processes are not limited to the illustrated applications.

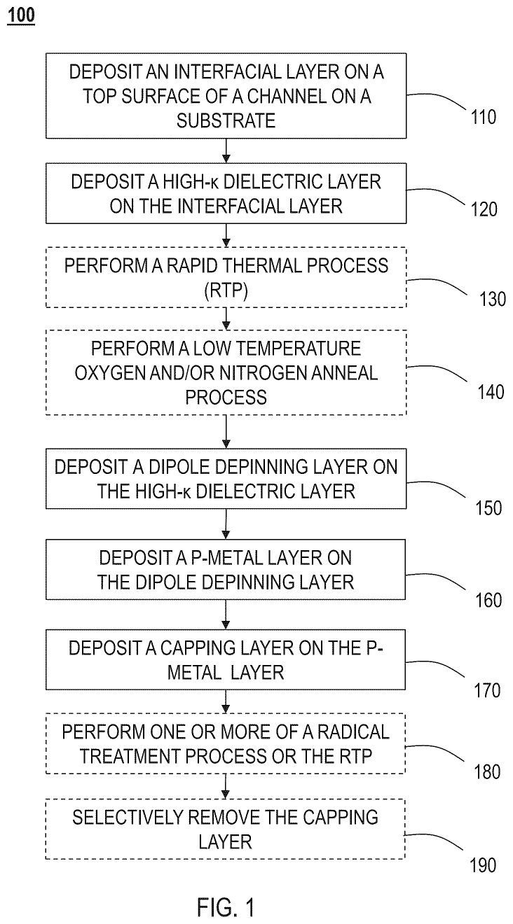

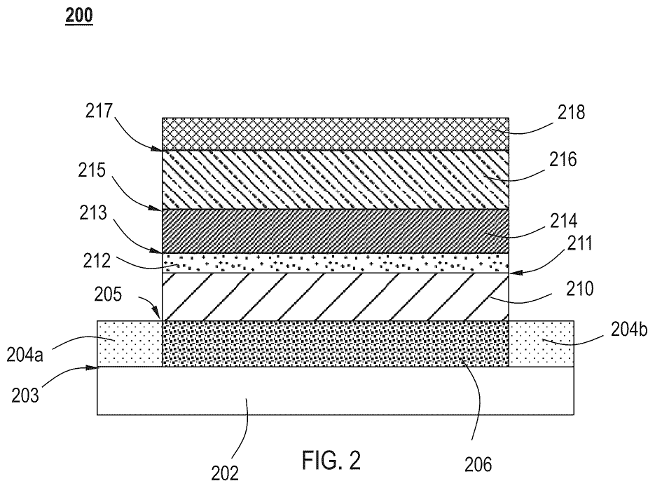

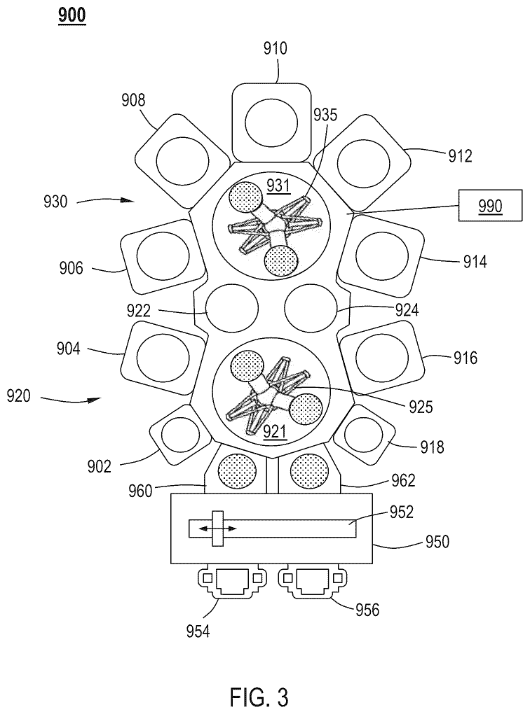

FIG. 1 illustrates a process flow diagram of a method 100 of manufacturing an electronic device according to one or more embodiments of the present disclosure. The method 100 is described below with respect to FIGS. 2 and 3. The method 100 of one or more embodiments may be part of a multi-step fabrication process of a semiconductor device and/or an electronic device. FIG. 2 illustrates a cross-sectional view of a portion of an electronic device 200. In one or more embodiments, the electronic device 200 shown in FIG. 2 is representative of a PMOS transistor.

The method 100 may be performed in any suitable process chamber or multi-chamber processing system, such as processing system 900 (i.e., a clustered-tool configuration without an intervening vacuum break). The processing system 900 can include processing chambers for fabricating the electronic devices 200, such as processing chambers independently configured for low-κ dielectric layer formation using a rapid thermal oxidation process or traditional wet deposition techniques, high-κ dielectric layer deposition, metal layer deposition, rapid thermal processing (RTP), low temperature oxygen (O₂) and/or nitrogen (N₂) annealing, radical treatment, vapor doping, and/or any other suitable processing chamber used for the fabrication of the electronic devices 200.

The operations of the method 100 can be performed in any suitable order. In one or more embodiments, the operations of the method 100 are performed sequentially in the order illustrated in FIG. 1. One or more of the operations of the method 100 may be repeated. One or more of the operations of the method 100 may not be performed, e.g., where the operation is denoted as optional using dashed lines in FIG. 1. It will be appreciated by the skilled artisan that the substrate on which the processes are performed on can be provided (e.g., made available for processing) with one or more operations already completed.

In one or more embodiments, the method 100 comprises, consists essentially of, or consists of: depositing an interfacial layer 210 on a top surface 205 of a channel 206 located between a source region 204a and a drain region 204b on a substrate 202 (operation 110); depositing a high-κ dielectric layer 212 on a top surface 211 of the interfacial layer 210 (operation 120); optionally, performing a rapid thermal process (RTP) (operation 130); optionally, performing a low temperature oxygen (O₂) and/or nitrogen (N₂) annealing process (operation 140); depositing a dipole depinning layer 214 on a top surface 213 of the high-κ dielectric layer 212 (operation 150); depositing a P-metal layer 216 on a top surface 215 of the dipole depinning layer 214 (operation 160); depositing a capping layer 218 on a top surface 217 of the P-metal layer 216 (operation 170); optionally, performing one or more of a radical treatment process or the RTP (operation 180); and optionally, selectively removing the capping layer (operation 190).

Advantageously, the method 100 combines deposition of a P-dipole material and P-metal material and advantageously obviates a dipole removal step, thereby simplifying the existing integration flow and reducing the integration costs.

The substrate 202 can be any suitable substrate material. In one or more embodiments, the substrate 202 comprises a semiconductor material, e.g., silicon (Si), carbon (C), germanium (Ge), silicon germanium (SiGe), gallium arsenide (GaAs), indium phosphate (InP), indium gallium arsenide (InGaAs), indium aluminum arsenide (InAlAs), germanium (Ge), silicon germanium (SiGe), other semiconductor materials, or any combination thereof. In one or more embodiments, the substrate 202 comprises one or more of silicon (Si), silicon oxide (SiOx), germanium (Ge), gallium (Ga), arsenic (As), indium (In), phosphorus (P), or selenium (Se). In one or more embodiments, the substrate 202 comprises at least one semiconductor material and at least one dielectric material.

Although a few examples of materials from which the substrate 202 may be formed are described herein, any material that may serve as a foundation upon which passive and active electronic devices (e.g., transistors, memories, capacitors, inductors, resistors, switches, integrated circuits, amplifiers, optoelectronic devices, or any other electronic devices) may be built falls within the spirit and scope of the present disclosure.

In one or more embodiments, the substrate 202 comprises one or more of silicon (Si) or silicon oxide (SiOx). In one or more embodiments, the substrate 202 is a p-type or n-type substrate. As used herein, the term “n-type” refers to semiconductors that are created by doping an intrinsic semiconductor with an electron donor element during manufacture. The term n-type comes from the negative charge of the electron. In n-type semiconductors, electrons are the majority carriers and holes are the minority carriers. As used herein, the term “p-type” refers to the positive charge of a well (or hole). As opposed to n-type semiconductors, p-type semiconductors have a larger hole concentration than electron concentration. In p-type semiconductors, holes are the majority carriers and electrons are the minority carriers.

In one or more embodiments, a source region 204a is on the top surface 203 of the substrate 202. In one or more embodiments, the source region 204a has a source and a source contact (not illustrated). A drain region 204b is on the top surface 203 of the substrate 202 opposite the source region 204a. In one or more embodiments, the drain region 204b has a drain and a drain contact (not illustrated).

In one or more embodiments, the source region 204a and/or the drain region 204b can be any suitable material known to the skilled artisan. In one or more embodiments, the source region 204a and/or the drain region 204b may have more than one layer. For example, the source region 204a and/or the drain region 204b may independently comprise three layers. In one or more embodiments, the source region 204a and the drain region 204b may independently comprise one or more of copper (Cu), cobalt (Co), tungsten (W), titanium (Ti), molybdenum (Mo), nickel (Ni), ruthenium (Ru), silver (Ag), gold (Au), iridium (Ir), platinum (Pt), phosphorus (P), germanium (Ge), silicon (Si), aluminum (Al), or zirconium (Zr). In some embodiments, the source region 204a and the drain region 204b may independently comprise a bottom layer of silicon with doped epi (e.g., SiGe, SiP, and the like), a second layer of silicide, which may contain nickel (Ni), titanium (Ti), aluminum (Al), and the like, and a third, or top, layer which may be a metal such as, but not limited to, cobalt, tungsten, ruthenium, and the like. In some embodiments, the source region 204a and the drain region 204b may be raised source/drain regions formed by EPI growth.

In one or more embodiments, the source contact and/or the drain contact may independently be selected from one or more of nitrogen (N), copper (Cu), cobalt (Co), tungsten (W), titanium (Ti), molybdenum (Mo), nickel (Ni), ruthenium (Ru), silver (Ag), gold (Au), iridium (Ir), tantalum (Ta), or platinum (Pt). In one or more embodiments, formation of the source contact and/or the drain contact is conducted by any suitable process known to the skilled artisan, including, but not limited to ALD, CVD, PVD, MBE, MOCVD, spin-on, or other insulating layer deposition techniques known to the skilled artisan.

The channel 206 is located between the source region 204a and the drain region 204b. In one or more embodiments, the channel 206 comprises silicon (Si). In one or more embodiments, the channel 206 comprises silicon germanium (SiGe).

In one or more embodiments, at operation 110, the interfacial layer 210 is deposited on or directly on the top surface 205 of the channel 206. The interfacial layer 210 comprises one or more of silicon (Si), silicon oxide (SiOx), doped silicon, doped silicon oxide, or spin-on dielectrics. In one or more embodiments, the interfacial layer 210 has a thickness in a range of 1 Å to 10 Å. In one or more embodiments, the interfacial layer 210 is formed directly on the top surface 203 of the substrate 202.

The interfacial layer 210 is formed directly on the top surface 203 of the substrate 202 using a deposition technique, such as, but not limited to, ALD, CVD, PVD, MBE, MOCVD, spin-on, or other insulating layer deposition techniques known to the skilled artisan. In one or more embodiments, the interfacial layer 210 may be formed by etching and an oxide forming on the top surface 203 of the substrate 202.

In some embodiments, at operation 110, a wet chemistry technique is performed to form the interfacial layer 210. The wet chemistry technique may be any suitable technique known to the skilled artisan. In some embodiments, the wet chemistry technique includes a pre-clean process. In some embodiments, the pre-clean process includes using a SC-1 solution comprising one or more of ozone, ammonium hydroxide or hydrogen peroxide. In some embodiments, the pre-clean process includes using a SC-1 solution without ozone, ammonium hydroxide or hydrogen peroxide. In some embodiments, after using the SC-1 solution, the pre-clean process includes using dilute hydrofluoric acid (dilute HF), including greater than 100:1, such as 130:1 dilute HF, to etch away native oxide on the substrate to form a hydrophobic surface (i.e., the interfacial layer).

In some embodiments, at operation 110, a rapid thermal oxidation process is used to form the interfacial layer 210. The rapid thermal oxidation process may be any suitable process known to the skilled artisan. In some embodiments, at operation 110 comprising the rapid thermal oxidation process, the interfacial layer 210, e.g., a silicon oxide (SiOx) layer, is grown on top surface 203 of the substrate 202.

In one or more embodiments, at operation 120, the high-κ dielectric layer 212 is deposited on or directly on a top surface 211 of the interfacial layer 210 using a deposition technique, such as, but not limited to, ALD, CVD, PVD, MBE, MOCVD, spin-on, or other insulating layer deposition techniques known to the skilled artisan. In some embodiments, at operation 120, the high-κ dielectric layer 212 is conformally deposited by ALD.

In some embodiments, the high-κ dielectric layer 212 comprises one or more of hafnium oxide (HfOx), zirconium oxide (ZrOx), hafnium zirconium (HfZr), or hafnium zirconium oxide (HfZrOx). In some embodiments, the high-κ dielectric layer 212 comprises hafnium oxide (HfOx). In one or more embodiments, the high-κ dielectric layer 212 has a thickness in a range of from about 10 Å to about 25 Å. In one or more embodiments, the high-κ dielectric layer 212 has a thickness of 20 Å.

In one or more embodiments, at operation 130, the method 100 optionally includes performing a rapid thermal process (RTP). In one or more embodiments, the RTP of operation 130 is performed prior to the low temperature oxygen (O₂) and/or nitrogen (N₂) annealing process of operation 140. In one or more embodiments, the RTP of operation 130 is performed after the low temperature oxygen (O₂) and/or nitrogen (N₂) annealing process of operation 140. In one or more embodiments, the RTP of operation 130 is performed prior to depositing the dipole depinning layer 214 at operation 150.

The RTP may be any suitable process known to the skilled artisan. As used herein, the RTP can include one or more of a spike anneal process, a nanosecond anneal process, or a millisecond anneal process.

In one or more embodiments, the spike anneal process includes exposing the substrate 202 at a temperature of less than or equal to 950° C. in a nitrogen (N₂) ambient environment for 15 seconds. In one or more embodiments, the spike anneal process is performed at a temperature in a range of from 700° C. to 950° C. The RTP may include a nanosecond anneal process (flash anneal process) or a millisecond anneal process (laser anneal process), as will be understood by the skilled artisan. In one or more embodiments, the nanosecond anneal process and the millisecond anneal process are independently performed at a temperature less than or equal to 1150° C.

In one or more embodiments, at operation 140, the method 100 optionally includes performing a low temperature oxygen (O₂) and/or nitrogen (N₂) annealing process. The low temperature oxygen (O₂) and/or nitrogen (N₂) annealing process is performed at a temperature of less than or equal to 450° C.

The low temperature oxygen (O₂) annealing process is performed in a rapid thermal processing chamber in oxygen ambient at a temperature of less than or equal to 450° C. in spike mode or in soak mode.

As used herein, “spike mode” refers to a type of annealing process in which the target temperature is reached and maintained for greater than 0 seconds to less than or equal to 2 seconds, the heater is turned off, and the temperature gradually decreases to room temperature. As used herein, “soak mode” refers to a type of annealing process in which the target temperature is reached and maintained for greater than 0 seconds to less than or equal to 60 seconds, such as 30 seconds, or 5 seconds, the heater is turned off, and the temperature gradually decreases to room temperature. In one or more embodiments, the target temperature is maintained for a longer period of time in soak mode than in spike mode.

The low temperature nitrogen (N₂) annealing process is performed in a rapid thermal processing chamber in nitrogen ambient at a temperature of less than or equal to 450° C. in spike mode or in soak mode.

In one or more embodiments, a low temperature fluorine exposure process is performed in a rapid thermal processing chamber in fluorine ambient at a temperature of less than or equal to 450° C. in spike mode or in soak mode. Advantageously, it has been found that the low temperature fluorine exposure process improves reliability of the electronic device 200 (i.e., the PMOS transistor).

In one or more embodiments, the low temperature oxygen (O₂) and/or nitrogen (N₂) annealing process and the low temperature fluorine exposure process are both performed as part of the method 100. In one or more embodiments, the low temperature fluorine exposure process is not performed when the low temperature oxygen (O₂) and/or nitrogen (N₂) annealing process is performed, or vice versa.

In one or more embodiments, the RTP advantageously heals oxygen vacancies present in the high-κ dielectric layer 212 and/or interfacial layer 210. In one or more embodiments, the RTP of operation 130, performed after the low temperature oxygen (O₂) and/or nitrogen (N₂) annealing process of operation 140, advantageously improves the physical properties of the high-κ dielectric layer 212 and interfacial layer 210.

In one or more embodiments, at operation 150, the dipole depinning layer 214 is deposited on or directly on the top surface 213 of the high-κ dielectric layer 212. The dipole depinning layer 214 may be deposited by any suitable process known to the skilled artisan, including, but not limited to ALD, CVD, PVD, MBE, MOCVD, spin-on, radical-assisted processes, or other insulating layer deposition techniques known to the skilled artisan. The dipole depinning layer 214 may be deposited as a single layer or a multilayer film. The dipole depinning layer 214 may be deposited to a predetermined thickness. In some embodiments, the dipole depinning layer 214 has a thickness in a range of from >0 Å to 15 Å, including in a range of from 1 Å to 10 Å, or a range of from 1 Å to 5 Å.

In one or more embodiments, the dipole depinning layer 214 advantageously minimizes flatband voltage (V_{fb}) rolloff at low equivalent oxide thickness (EOT). In one or more embodiments, the dipole depinning layer 214 may provide a mid-gap work function, e.g., in a range of from about 4.4 eV to about 4.7 eV.

In one or more embodiments, the dipole depinning layer 214 may comprise any suitable material known to the skilled artisan. In some embodiments, the material for the dipole depinning layer 214 is selected based on its affinity for oxygen.

In one or more embodiments, the dipole depinning layer 214 comprises a metal selected from one or more of aluminum (Al), tantalum (Ta), titanium (Ti), molybdenum (Mo), tungsten (W), vanadium (V), niobium (Nb), ruthenium (Ru), antimony (Sb), and tin (Sn).

In one or more embodiments, the dipole depinning layer 214 comprises one or more of tantalum silicide (TaSix), tantalum silicon nitride (TaSiN), tantalum nitride (TaN), tantalum oxynitride (TaON), tantalum carbonitride (TaCN), titanium silicide (TiSix), titanium silicon nitride (TiSiN), titanium aluminum nitride (TiAlN), titanium oxynitride (TiON), tungsten silicide (WSix), tungsten silicon nitride (WSiN), tungsten carbonitride (WCN), aluminum silicon nitride (AlSiN), aluminum nitride (AlN), niobium nitride (NbN), selenium (Se), selenium nitride (SeN), graphene, titanium selenide (TiSe), titanium selenium nitride (TiSeN), and transition metal dichalcogenides.

In one or more embodiments, the transition metal dichalcogenides comprise one or more of molybdenum sulfide (MoS₂), molybdenum telluride (MoTe₂), molybdenum selenide (MoSe), tungsten sulfide (WS₂), tungsten telluride (WTe₂), or tungsten selenide (WSe).

In one or more embodiments, the RTP is of operation 130 is performed after depositing the dipole depinning layer 214 at operation 150 and prior to depositing the P-metal layer 216 at operation 160.

Without intending to be bound by theory, it is thought that performing the RTP after the dipole depinning layer 214 is deposited, drives an increased number of metal atoms from the dipole depinning layer 214 into the interface between the interfacial layer 210 and the high-κ dielectric layer 212, as compared to methods where annealing does not occur.

The RTP drives atoms from the dipole depinning layer 214 into the interface between the interfacial layer 210 and the high-κ dielectric layer 212, such that the interface between the interfacial layer 210 and the high-κ dielectric layer 212 comprises properties of the dipole depinning layer 214.

Advantageously, in one or more embodiments, the dipole depinning layer 214 has depinning properties, e.g., the dipole depinning layer 214 increases the flatband voltage (V_{fb}) by more than 100 mV when compared to a PMOS stack that does not have a depinning layer, thereby mitigating Fermi level pinning effect, and the dipole depinning layer 214 acts as a dipole forming layer upon rapid thermal processing (RTP) and can form dipoles, thereby boosting threshold voltage (Vₜ) of the electronic device 200 (i.e., the PMOS transistor).

In one or more embodiments, the P-metal layer 216 is deposited on or directly on the top surface 215 of the dipole depinning layer 214. The P-metal layer 216 may be deposited by any suitable process known to the skilled artisan, including, but not limited to ALD, CVD, PVD, MBE, MOCVD, spin-on, radical-assisted processes, or other insulating layer deposition techniques known to the skilled artisan. In one or more embodiments, the P-metal layer 216 is deposited by atomic layer deposition (ALD).

In one or more embodiments, the P-metal layer 216 is deposited by atomic layer deposition (ALD) at a temperature in a range of from about 200° C. to about 600° C. In one or more embodiments, the P-metal layer 216 is deposited by atomic layer deposition (ALD) at a temperature in a range of from about 200° C. to about 450° C.

The P-metal layer 216 may be deposited as a single layer or a multilayer film. The P-metal layer 216 may be deposited to a predetermined thickness. In some embodiments, the P-metal layer 216 has a thickness in a range of from >0 Å to 50 Å. In some embodiments, the P-metal layer 216 has a thickness in a range of from 10 Å to 20 Å. In some embodiments, the P-metal layer 216 has a thickness of 20 Å.

The P-metal layer 216 can comprise any suitable metal. In one or more embodiments, the P-metal layer 216 comprises a high work function metal or metal nitride. In some embodiments, doping more electronegative elements into a metal nitride, e.g., molybdenum nitride (MoN), titanium nitride (TiN), and the like, provides a P-metal layer 216 with the desired work function tunability without changing the thickness of the P-metal layer 216.

In one or more embodiments, the P-metal layer 216 comprises a metal selected from one or more of titanium (Ti), tungsten (W), tantalum (Ta), platinum (Pt), iridium (Ir), nickel (Ni), palladium (Pd), cobalt (Co), ruthenium (Ru), niobium (Nb), and molybdenum (Mo). In one or more embodiments, the P-metal layer 216 comprises one or more of titanium nitride (TiN), selenium doped titanium nitride (Se doped-TiN), tellurium doped titanium nitride (Te-doped TiN), antimony doped titanium nitride (Sb doped-TiN), germanium doped titanium nitride (Ge doped-TiN), gallium doped titanium nitride (Ga doped-TiN), niobium nitride (NbN), selenium doped niobium nitride (Se doped-NbN), tellurium doped niobium nitride (Te-doped NbN), antimony doped niobium nitride (Sb doped-NbN), germanium doped niobium nitride (Ge doped-NbN), gallium doped niobium nitride (Ga doped-NbN), molybdenum nitride (MoN), carbon doped molybdenum nitride (C-doped MoN), selenium doped molybdenum nitride (Se-doped MoN), tellurium doped molybdenum nitride (Te-doped MoN), antimony doped molybdenum nitride (Sb doped-MoN), germanium doped molybdenum nitride (Ge doped-MoN), or gallium doped molybdenum nitride (Ga doped-MoN), and the like.

Advantageously, the method 100 combines deposition of a P-dipole material and P-metal material and advantageously obviates a dipole removal step, thereby simplifying the existing integration flow and reducing the integration costs.

In one or more embodiments, at operation 170, the method 100 comprises depositing a capping layer 218 on or directly on the top surface 217 of the P-metal layer 216 to neutralize charges in the interfacial layer 210 and/or high-κ dielectric layer 212 and passivate oxygen vacancies. In one or more embodiments, depositing the capping layer 218 at operation 170 may be used to control ambient atmosphere from interacting with the P-metal layer 216 and causing an interaction on equivalent oxide thickness (EOT).

In one or more embodiments, the capping layer 218 is deposited using one of deposition techniques, such as, but not limited to, ALD, CVD, PVD, MBE, MOCVD, spin-on, or other insulating layer deposition techniques known to the skilled artisan. In one or more specific embodiments, the capping layer 218 is deposited by atomic layer deposition (ALD).

In one or more embodiments, the capping layer 218 may have any suitable thickness. In some embodiments, the capping layer 218 has a thickness in a range of 5 Å to 20 Å.

In one or more embodiments, the capping layer 218 can comprise any suitable material. In one or more embodiments, the capping layer 218 comprises one or more of titanium nitride (TiN), titanium silicon nitride (TiSiN), tantalum nitride (TaN), niobium nitride (NbN), lanthanum nitride (LaN), amorphous silicon (a-Si), or titanium nitride with amorphous silicon (TiN+a-Si).

In one or more embodiments, at operation 180, the method 100 optionally includes performing one or more of a radical treatment process or the RTP. The radical treatment process and/or the RTP can independently be performed after depositing the capping layer 218 at operation 170, and/or prior to depositing the P-metal layer 216 at operation 160, and/or prior to depositing the capping layer 218 at operation 170.

In one or more embodiments, the radical treatment process includes introduction of radicals comprising one or more of H*, OH*, O*, N₂*, NH₃* or H2O*. In some embodiments, the radicals are generated by forming a plasma from a radical gas. The plasma can be generated by any suitable plasma source. In some embodiments, the plasma is generated by a remote plasma source.

In one or more embodiments, at operation 180, the method 100 optionally includes performing a vapor doping process. In one or more embodiments, for example, the vapor doping process occurs by soaking a surface with a dopant to form atoms of the dopant on the surface without using a reactant. The dopant can be any suitable dopant that will bond with will bond with OH and form a monolayer of oxide. In one or more embodiments, the dopant comprises a halogen-containing precursor. In one or more embodiments, the dopant comprises one or more of sulfur (S), or selenium (Se). In one or more embodiments, for example, the interfacial layer 210 and/or the high-κ dielectric layer 212 is soaked with a dopant (e.g., titanium tetrachloride (TiCl₄)) to form a monolayer of titanium oxide (TiOx) on the interfacial layer 210 and/or the high-κ dielectric layer 212, respectively.

In one or more embodiments, at operation 190, the method 100 optionally includes performing the low temperature oxygen (O₂) and/or nitrogen (N₂) annealing process. The low temperature oxygen (O₂) and/or nitrogen (N₂) annealing process of operation 190 can be the same as the process of operation 140.

The low temperature oxygen (O₂) and/or nitrogen (N₂) annealing process can be performed after depositing the capping layer 218 at operation 170, and/or prior to depositing the P-metal layer 216 at operation 160, and/or prior to depositing the capping layer 218 at operation 170.

In one or more embodiments, at operation 190, the method 100 optionally includes selectively removing the capping layer 218. In one or more embodiments, the capping layer 218 is the only layer from the electronic device 200 that is removed. Advantageously, the method 100 combines deposition of a P-dipole material and P-metal material and advantageously obviates a dipole removal step, thereby simplifying the existing integration flow and reducing the integration costs.

The capping layer 218 can be selectively removed at operation 190 by any suitable process. In one or more embodiments, the capping layer 218 is selectively removed by chemical mechanical planarization (CMP).

The operations of the method 100 can be performed in any suitable order. In one or more embodiments, the operations of the method 100 are performed sequentially in the order illustrated in FIG. 1. One or more of the operations of the method 100 may be repeated. The method 100 can include any other suitable operations, as will be understood and appreciated by the skilled artisan, to complete the fabrication of the electronic device 200.

In one or more embodiments, the method 100 comprises, consists essentially of, or consists of: depositing the interfacial layer 210 on the top surface 205 of the channel 206 located between the source region 204a and the drain region 204b on the substrate 202 (operation 110); depositing the high-κ dielectric layer 212 on the top surface 211 of the interfacial layer 210 (operation 120); depositing the dipole depinning layer 214 on the top surface 213 of the high-κ dielectric layer 212 (operation 150); performing the rapid thermal process (RTP) (operation 130); depositing the P-metal layer 216 on the top surface 215 of the dipole depinning layer 214 (operation 160); depositing the capping layer 218 on the top surface 217 of the P-metal layer 216 (operation 170); and optionally, performing one or more of the radical treatment process or the RTP (operation 180).

In one or more embodiments, the method 100 comprises, consists essentially of, or consists of: depositing the interfacial layer 210 on the top surface 205 of the channel 206 located between the source region 204a and the drain region 204b on the substrate 202 (operation 110); depositing the high-κ dielectric layer 212 on the top surface 211 of the interfacial layer 210 (operation 120); depositing the dipole depinning layer 214 on the top surface 213 of the high-κ dielectric layer 212 (operation 150); performing the low temperature oxygen (O₂) and/or nitrogen (N₂) annealing process (operation 140); performing the rapid thermal process (RTP) (operation 130); depositing the P-metal layer 216 on the top surface 215 of the dipole depinning layer 214 (operation 160); depositing the capping layer 218 on the top surface 217 of the P-metal layer 216 (operation 170); and optionally, performing one or more of a radical treatment process or the RTP (operation 180).

In one or more embodiments, the method 100 comprises, consists essentially of, or consists of: depositing the interfacial layer 210 on the top surface 205 of the channel 206 located between the source region 204a and the drain region 204b on the substrate 202 (operation 110); depositing the high-κ dielectric layer 212 on the top surface 211 of the interfacial layer 210 (operation 120); depositing the dipole depinning layer 214 on the top surface 213 of the high-κ dielectric layer 212 (operation 150); performing the rapid thermal process (RTP) (operation 130); performing a low temperature fluorine exposure process as described herein; performing the low temperature oxygen (O₂) and/or nitrogen (N₂) annealing process (operation 140); depositing the P-metal layer 216 on the top surface 215 of the dipole depinning layer 214 (operation 160); depositing the capping layer 218 on the top surface 217 of the P-metal layer 216 (operation 170); and optionally, performing one or more of a radical treatment process or the RTP (operation 180).

Further embodiments of the disclosure are directed to an electronic device, e.g., the electronic device 200 fabricated in accordance with the method 100. In one or more embodiments, the electronic device 200 comprises the interfacial layer 210 comprising silicon oxide (SiOx) on the top surface 205 of the channel 206 (comprising silicon (Si)) located between the source region 204a and the drain region 204b on the substrate 202; the high-κ dielectric layer 212 comprising hafnium oxide (HfOx) or hafnium zirconium oxide (HfZrOx) directly on the interfacial layer 210; the dipole depinning layer 214 directly on the top surface 213 of the high-κ dielectric layer 212; the P-metal layer 216 directly on the top surface 215 of the dipole depinning layer 214; and the capping layer 218 directly on the top surface 217 of the P-metal layer 216.

Additional embodiments of the disclosure are directed to the processing system 900 (i.e., the clustered-tool configuration referenced herein) shown in FIG. 3, for the formation of the electronic devices (e.g., electronic device 200) and methods (e.g., method 100) described. In one or more embodiments, the processing system 900 is integrated, such that each of the operations of the methods described are performed in situ in the processing system 900, without an intervening vacuum break.

The processing system 900 includes at least one central transfer station 921, 931 with a plurality of sides. A robot 925, 935 is positioned within the central transfer station 921, 931 and is configured to move a robot blade and a wafer (i.e., the substrate 202) to each of the plurality of sides.

The processing system 900 comprises a plurality of processing chambers 902, 904, 906, 908, 910, 912, 914, 916, and 918, also referred to as process stations, connected to the low-κ dielectric layer formation using a rapid thermal oxidation process or traditional wet deposition techniques central transfer station 921, 931. The various processing chambers provide separate processing regions isolated from adjacent process stations.

The processing system 900 can include any suitable number of processing chambers. The processing system 900 is configured to process any suitable number of substrates 202. In one or more embodiments, the processing system 900 is configured to perform one or more operations of the method 100 simultaneously on a batch of substrates (e.g., substrate 202) that includes any suitable number of substrates 202.

The processing system 900 can include processing chambers for fabricating the electronic devices 200, such as processing chambers independently configured for low-κ dielectric layer formation using a rapid thermal oxidation process or traditional wet deposition techniques, high-κ dielectric layer deposition, metal layer deposition, rapid thermal processing (RTP), low temperature oxygen (O₂) and/or nitrogen (N₂) annealing, radical treatment, vapor doping, and/or any other suitable processing chamber used for the fabrication of the electronic devices 200.

The particular arrangement of processing chambers and components can be varied depending on the processing system and should not be taken as limiting the scope of the disclosure.

In the embodiment shown in FIG. 3, a factory interface 950 is connected to a front of the processing system 900. The factory interface 950 includes a loading chamber 954 and an unloading chamber 956 on a front 951 of the factory interface 950. While the loading chamber 954 is shown on the left and the unloading chamber 956 is shown on the right, those skilled in the art will understand that this is merely representative of one possible configuration.

The size and shape of the loading chamber 954 and unloading chamber 956 can vary depending on, for example, the substrates being processed in the processing system 900. In the embodiment shown, the loading chamber 954 and unloading chamber 956 are sized to hold a wafer cassette with a plurality of wafers (i.e., a plurality of substrates) positioned within the cassette.

A robot 952 is within the factory interface 950 and can move between the loading chamber 954 and the unloading chamber 956. The robot 952 is capable of transferring a wafer (i.e., a substrate) from a cassette in the loading chamber 954 through the factory interface 950 to load lock chamber 960. The robot 952 is also capable of transferring a wafer (i.e., a substrate) from the load lock chamber 962 through the factory interface 950 to a cassette in the unloading chamber 956. As will be understood by those skilled in the art, the factory interface 950 can have more than one robot 952. For example, the factory interface 950 may have a first robot that transfers wafers between the loading chamber 954 and load lock chamber 960, and a second robot that transfers wafers between the load lock chamber 962 and the unloading chamber 956.

The processing system 900 shown in FIG. 3 has a first section 920 and a second section 930. The first section 920 is connected to the factory interface 950 through load lock chambers 960, 962. The first section 920 includes a first transfer station 921 with at least one robot 925 positioned therein. The robot 925 is also referred to as a robotic wafer transport mechanism. The first transfer station 921 is centrally located with respect to the load lock chambers 960, 962, processing chambers 902, 904, 916, 918, and pass-through chambers 922, 924. The robot 925 of some embodiments is a multi-arm robot capable of independently moving more than one wafer at a time. In one or more embodiments, the first transfer station 921 comprises more than one robotic wafer transfer mechanism. The robot 925 in first transfer station 921 is configured to move wafers between the chambers around the first transfer station 921. Individual wafers are carried upon a wafer transport blade that is located at a distal end of the first robotic mechanism.

After processing a wafer in the first section 920, the wafer can be passed to the second section 930 through a pass-through chamber. For example, the pass-through chambers 922, 924 can be uni-directional or bi-directional pass-through chambers. The pass-through chambers 922, 924 can be used, for example, to cryo cool the wafer before processing in the second section 930 or to allow wafer cooling or post-processing before moving back to the first section 920.

A system controller 990 is in communication with the first robot 925, second robot 935, first plurality of processing chambers 902, 904, 916, 918 and second plurality of processing chambers 906, 908, 910, 912, 914. The system controller 990 can be any suitable component that can control the processing chambers and robots. For example, the system controller 990 can be a computer including a central processing unit, memory, suitable circuits, and storage.

Processes may generally be stored in the memory of the system controller 990 as a software routine that, when executed by the processor, causes the process chamber to perform processes of the present disclosure. The software routine may also be stored and/or executed by a second processor (not shown) that is remotely located from the hardware being controlled by the processor. Some or all of the methods, such as method 100, of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor, transforms the general-purpose computer into a specific purpose computer (controller) that controls the chamber operation such that the processes are performed.

Embodiments of the disclosure are directed to a non-transitory computer readable medium. In one or more embodiments, the non-transitory computer readable medium includes instructions that, when executed by a controller of a processing system 900, causes the processing system 900 to perform the operations of any of the methods described herein. In one or more embodiments, the controller causes the processing system 900 to perform the operations of method 100.

In one or more embodiments, the processing system 900 comprises a central transfer station 921, 931 comprising at least one robot 925, 935 configured to move a wafer one or more processing stations to perform the methods described herein, e.g., the method 100.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A method of manufacturing an electronic device, the method comprising:
depositing an interfacial layer on a top surface of a channel located between a source region and a drain region on a substrate;
depositing a high-κ dielectric layer on the interfacial layer;
depositing a dipole depinning layer on the high-κ dielectric layer;
depositing a P-metal layer on the dipole depinning layer; and
depositing a capping layer on the P-metal layer, wherein the method is performed in situ in an integrated processing system.

2. The method of claim 1, wherein the interfacial layer comprises one or more of silicon (Si), silicon oxide (SiOx), doped silicon, doped silicon oxide, or spin-on dielectrics.

3. The method of claim 1, wherein the high-κ dielectric layer comprises one or more of hafnium oxide (HfOx), zirconium oxide (ZrOx), hafnium zirconium (HfZr), or hafnium zirconium oxide (HfZrOx).

4. The method of claim 1, wherein the dipole depinning layer has a work function in a range of from about 4.4 eV to about 4.7 eV.

5. The method of claim 1, wherein the dipole depinning layer comprises a metal selected from one or more of aluminum (Al), tantalum (Ta), titanium (Ti), molybdenum (Mo), tungsten (W), vanadium (V), niobium (Nb), ruthenium (Ru), antimony (Sb), and tin (Sn).

6. The method of claim 5, wherein the dipole depinning layer comprises one or more of tantalum silicide (TaSix), tantalum silicon nitride (TaSiN), tantalum nitride (TaN), tantalum oxynitride (TaON), tantalum carbonitride (TaCN), titanium silicide (TiSix), titanium silicon nitride (TiSiN), titanium aluminum nitride (TiAlN), titanium oxynitride (TiON), tungsten silicide (WSix), tungsten silicon nitride (WSiN), tungsten carbonitride (WCN), aluminum silicon nitride (AlSiN), aluminum nitride (AlN), niobium nitride (NbN), selenium (Se), selenium nitride (SeN), graphene, titanium selenide (TiSe), titanium selenium nitride (TiSeN), and transition metal dichalcogenides.

7. The method of claim 6, wherein the transition metal dichalcogenides comprise one or more of molybdenum sulfide (MoS₂), molybdenum telluride (MoTe₂), molybdenum selenide (MoSe), tungsten sulfide (WS₂), tungsten telluride (WTe₂), or tungsten selenide (WSe).

8. The method of claim 1, wherein the P-metal layer comprises a metal selected from one or more of titanium (Ti), tungsten (W), tantalum (Ta), platinum (Pt), iridium (Ir), nickel (Ni), palladium (Pd), cobalt (Co), ruthenium (Ru), niobium (Nb), and molybdenum (Mo).

9. The method of claim 8, wherein the P-metal layer comprises one or more of titanium nitride (TiN), selenium doped titanium nitride (Se doped-TiN), tellurium doped titanium nitride (Te-doped TiN), antimony doped titanium nitride (Sb doped-TiN), germanium doped titanium nitride (Ge doped-TiN), gallium doped titanium nitride (Ga doped-TiN), niobium nitride (NbN), selenium doped niobium nitride (Se doped-NbN), tellurium doped niobium nitride (Te-doped NbN), antimony doped niobium nitride (Sb doped-NbN), germanium doped niobium nitride (Ge doped-NbN), gallium doped niobium nitride (Ga doped-NbN), molybdenum nitride (MoN), carbon doped molybdenum nitride (C-doped MoN), selenium doped molybdenum nitride (Se-doped MoN), tellurium doped molybdenum nitride (Te-doped MoN), antimony doped molybdenum nitride (Sb doped-MoN), germanium doped molybdenum nitride (Ge doped-MoN), or gallium doped molybdenum nitride (Ga doped-MoN), and the like.

10. The method of claim 1, wherein the capping layer comprises one or more of titanium nitride (TiN), titanium silicon nitride (TiSiN), tantalum nitride (TaN), niobium nitride (NbN), lanthanum nitride (LaN), amorphous silicon (a-Si), or titanium nitride with amorphous silicon (TiN+a-Si).

11. The method of claim 1, further comprising performing a rapid thermal process (RTP) prior to depositing the dipole depinning layer.

12. The method of claim 11, wherein the RTP includes one or more of a spike anneal process, a nanosecond anneal process, or a millisecond anneal process.

13. The method of claim 11, further comprising performing the RTP after depositing the dipole depinning layer and prior to depositing the P-metal layer.

14. The method of claim 13, further comprising performing a low temperature oxygen (O₂) and/or nitrogen (N₂) annealing process prior to the RTP.

15. The method of claim 11, further comprising performing a radical treatment process and/or the RTP after depositing the capping layer.

16. The method of claim 14, further comprising performing the low temperature oxygen (O₂) and/or nitrogen (N₂) annealing process after depositing the capping layer.

17. The method of claim 16, further comprising selectively removing the capping layer.

18. A method of manufacturing an electronic device, the method comprising:
depositing an interfacial layer comprising silicon oxide (SiOx) on a top surface of a silicon (Si) channel located between a source region and a drain region on a substrate;
depositing a high-κ dielectric layer comprising hafnium oxide (HfOx) on the interfacial layer;
depositing a dipole depinning layer on the high-κ dielectric layer;
performing a low temperature oxygen (O₂) and/or nitrogen (N₂) annealing process;
performing a rapid thermal process (RTP), the RTP including one or more of a spike anneal process, a nanosecond anneal process, or a millisecond anneal process;
depositing a P-metal layer on the dipole depinning layer;
depositing a capping layer on the P-metal layer; and
selectively removing the capping layer, wherein the method is performed in situ in an integrated processing system, and the low temperature oxygen (O₂) and/or nitrogen (N₂) annealing process is performed prior to the RTP, or the RTP is performed prior to the low temperature oxygen (O₂) and/or nitrogen (N₂) annealing process.

19. A processing system comprising:
a central transfer station comprising a robot configured to move one or more substrates;
a plurality of process stations, each process station connected to the central transfer station and providing a processing region separated from processing regions of adjacent process stations; and
a controller connected to the central transfer station and the plurality of process stations, the controller configured to activate the robot to move the one or more substrates between process stations, and the robot configured to perform a method comprising:
depositing an interfacial layer on a top surface of a channel located between a source region and a drain region on the substrate;
depositing a high-κ dielectric layer on the interfacial layer;
depositing a dipole depinning layer on the high-κ dielectric layer;
depositing a P-metal layer on the dipole depinning layer; and
depositing a capping layer on the P-metal layer, wherein the method is performed in situ.

20. The processing system of claim 19, wherein the method further comprises one or more of the following operations:
performing a rapid thermal process (RTP) prior to depositing the dipole depinning layer, the RTP including one or more of a spike anneal process, a nanosecond anneal process, or a millisecond anneal process;
performing the RTP after depositing the dipole depinning layer and prior to depositing the P-metal layer;
performing a low temperature oxygen (O₂) and/or nitrogen (N₂) annealing process prior to the RTP that is performed after depositing the dipole depinning layer and prior to depositing the P-metal layer;
performing a radical treatment process and/or the RTP after depositing the capping layer;
performing the low temperature oxygen (O₂) and/or nitrogen (N₂) annealing process after depositing the capping layer; or
selectively removing the capping layer.
